(19) United States
(12) Patent Application Publication
(10) Pub. No.: US 2021/0173491 A1
(43) Pub. Date: Jun. 10, 2021

(54) KEYBOARD KEYS

(71) Applicant: HEWLETT-PACKARD DEVELOPMENT COMPANY, L.P., SPRING, TX (US)

(72) Inventors: OWEN P COLUMBUS, SPRING, TX (US); KEN MacLEAN, SPRING, TX (US)

(21) Appl. No.: 16/762,663

(22) PCT Filed: Feb. 8, 2018
(86) PCT No.: PCT/US2018/017395

§ 371 Date: May 8, 2020

(51) Int. Cl. G06F 3/02; H01H 13/7065; H01H 13/85

(52) U.S. Cl. CPC G06F 3/0202; H01H 13/7065; H01H 2203/008; H01H 2221/022; H01H 13/85

(57) ABSTRACT

Example implementations relate to keyboard keys. In some examples, a key of a keyboard may comprise a magnetic plate, a pole plate located adjacent to the magnetic plate, where a channel through the magnetic plate and the pole plate is located adjacent to a perimeter edge of the magnetic plate and a perimeter edge of the pole plate, a membrane covering the pole plate and the channel, a keycap located on top of the membrane, and a wire coil connected to the keycap and located in the channel.

### BACKGROUND

A keyboard can be utilized as an input device for an electronic device. For example, a keyboard can be utilized to provide inputs for letters, numbers, and/or other symbols or characters to an electronic device, among other possibilities. Examples of electronic devices having a keyboard can include laptop computers, desktop computers, and/or mobile devices, among other types of electronic devices.

### BRIEF DESCRIPTION OF THE DRAWINGS

FIG. 1 illustrates a perspective view of a cut-away of an example of a key consistent with the disclosure.

FIG. 2 illustrates a side view of an example of a key with a wire coil at different positions in a channel consistent with the disclosure.

FIG. 3 illustrates a side view of an example of a key with a wire coil being moved from a first position to a second position consistent with the disclosure.

FIG. 4 illustrates a side view of an example of a key with a magnetic plate and a pole plate having opposite poles consistent with the disclosure.

FIG. 5 illustrates a perspective view of an example of a key consistent with the disclosure.

FIG. 6 illustrates a perspective view of a cut-away of an example of a portion of a keyboard with keyboard keys consistent with the disclosure.

FIG. 7 illustrates a perspective view of an example of a key consistent with the disclosure.

### DETAILED DESCRIPTION

Keyboards can utilize mechanical mechanisms to provide key travel, hold the key parallel to an upper surface of the keyboard, set key feel, and/or register key presses, among other functions. As used herein, the term “keyboard” can, for example, refer to a device utilizing an arrangement of buttons (e.g., keys) to input information into a computing device. For example, a keyboard can utilize mechanical mechanisms such as scissor mechanisms or butterfly mechanisms for operation of keys of the keyboard. Utilizing these mechanisms can allow for keyboards to input characters, such as letters, numbers, and/or other symbols via the keys of the keyboard to a computing device. As used herein, the term “key” can, for example, refer to a switch mechanism to control an input to a computing device. As used herein, the term “computing device” can, for example, refer to a laptop computer, a desktop computer, a server, storage and/or networking equipment, among other types of computing devices.

A mechanical mechanism to operate keyboard keys can result in the keyboard being a certain thickness. For example, a mechanical mechanism for a key, as well as a thickness of a backplate and circuit board of the keyboard for operation of the keyboard keys can result in a minimum thickness of the keyboard in order to provide for operation of the keys of the keyboard. Additionally, the keyboard keys are typically in a fully extended position in a resting position. In such examples, the keyboard can account for a significant portion of an overall thickness of a computing device.

Keyboard keys according to the disclosure can utilize a wire coil for each keyboard key, where the wire coil is located in a channel located adjacent to a magnetic plate and a pole plate. A magnetic field can be generated by the magnetic plate and the pole plate in the channel where the wire coil of the key is located. By applying a direct-current (DC) voltage to the wire coil, the wire coil can generate an alternating-current (AC) when the wire coil moves in the channel, allowing for detection of a key press. As used herein, the term “key press” can, for example, refer to an event that produces an alphanumeric character input caused by a key being pressed down. As used herein, the term “direct-current” can, for example, refer to a unidirectional flow of electric charge. As used herein, the term “alternating-current” can, for example, refer to a bi-directional flow of electric charge.

In some implementations, keyboard keys according to the disclosure can allow for a thinner keyboard relative to a keyboard having mechanical mechanisms for the keys. The keys can be covered by a continuous membrane, allowing for a liquid resistant keyboard.

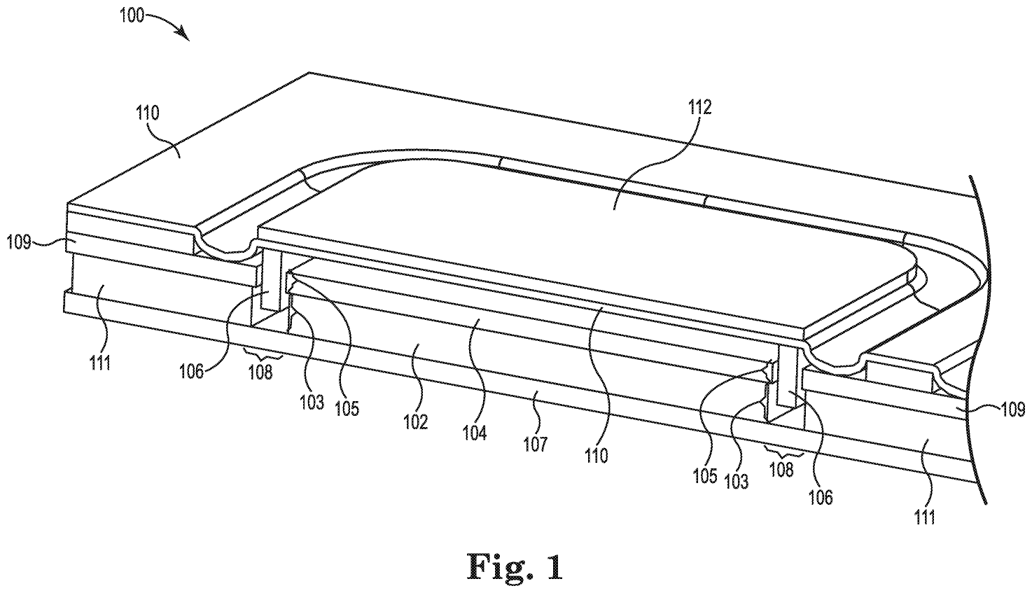

FIG. 1 illustrates a perspective view of a cut-away of an example of a key 100 consistent with the disclosure. As illustrated in FIG. 1, key 100 can include a magnetic plate 102, a top plate 109, a pole plate 104, a side magnet 111, a wire coil 106, a base plate 107, a channel 108, a membrane 110, and a keycap 112. Magnetic plate 102 can include a perimeter edge 103 of magnetic plate 102. Pole plate 104 can include a perimeter edge 105 of pole plate 104.

As illustrated in FIG. 1, key 100 can include magnetic plate 102. As used herein, the term “magnetic plate” can, for example, refer to a panel of material that produces a magnetic field. For example, magnetic plate 102 can be a neodymium magnet, where magnetic plate 102 is a material that is a neodymium, iron, and boron alloy. However, examples of the disclosure are not so limited. For example, magnetic plate 102 can be iron, nickel, a nickel-iron alloy such as Mu-metal, and/or any other magnetic materials, composites, rare-earth magnets, other magnetic alloys, and/or other combinations of materials.

Magnetic plate 102 can be adjacent to pole plate 104. As used herein, the term “pole plate” can, for example, refer to a panel of material that produces a magnetic field. For example, pole plate 104 can be a neodymium magnet, where pole plate 104 is a material that is a neodymium, iron, and boron alloy. However, examples of the disclosure are not so limited. For example, pole plate 104 can be iron, nickel, a nickel-iron alloy such as Mu-metal, and/or any other magnetic materials, composites, rare-earth magnets, other magnetic alloys, and/or other combinations of materials. In the orientation illustrated in FIG. 1, pole plate 104 can be located above magnetic plate 102.

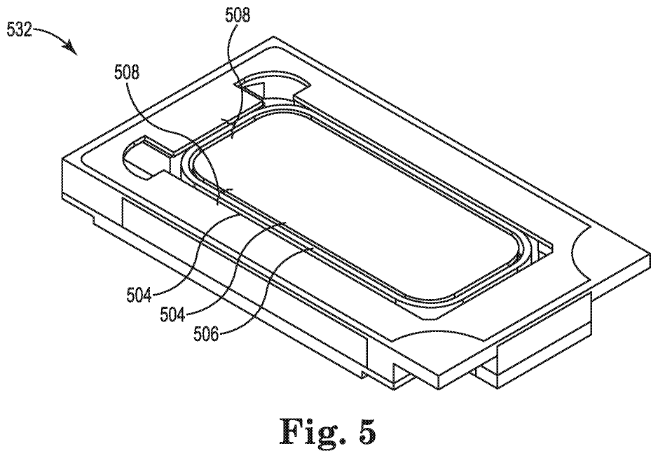

Magnetic plate 102 can include perimeter edge 103 of magnetic plate 102. As used herein, the term “perimeter edge” can, for example, refer to an edge around (e.g., that surrounds) a three-dimensional shape. For example, perimeter edge 103 can be an edge of magnetic plate 102 around magnetic plate 102. For instance, although not illustrated in FIG. 1 for clarity and so as not to obscure examples of the disclosure, magnetic plate 102 can be a rectangular shape with radiused corners. Perimeter edge 103 can be the edges of the rectangularly shaped magnetic plate 102, as is further illustrated in FIG. 5.

Pole plate 104 can include perimeter edge 105 of pole plate 104. For example, perimeter edge 105 can be an edge of pole plate 104 around pole plate 104. For instance, although not illustrated in FIG. 1 for clarity and so as not to obscure examples of the disclosure, pole plate 104 can be a rectangular shape having radiused corners. Perimeter edge 105 can be the edges of the rectangularly shaped pole plate 104.

Channel 108 can be adjacent to perimeter edge 103 of magnetic plate 102 and perimeter edge 105 of pole plate 104. As used herein, the term “channel” can, for example, refer to a narrow groove through material. For example, channel 108 can be a groove such that a space is created between magnetic plate 102 and side magnet 111, as well as between two sides of pole plate 104 and top plate 109.

Key 100 can include a side magnet 111. For example, as illustrated in FIG. 1, key 100 side magnet 111 can be on opposing sides of magnetic plate 102. Side magnet 111 and magnetic plate 102 can be separated by channel 108. As used herein, the term “side magnet” can, for example, refer to a material that produces a magnetic field. For example, side magnet 111 can be a neodymium magnet, where side magnet 111 is a material that is a neodymium, iron, and boron alloy. However, examples of the disclosure are not so limited. For example, side magnet 111 can be iron, nickel, a nickel-iron alloy such as Mu-metal, and/or any other magnetic materials, composites, rare-earth magnets, other magnetic alloys, and/or other combinations of materials.

Key 100 can include top plate 109. Top plate 109 can be adjacent to side magnet 111. For example, in the orientation illustrated in FIG. 1, top plate 109 can be located on top of and adjacent to side magnet 111. As used herein, the term “top plate” can, for example, refer to a panel of material that produces a magnetic field. For example, top plate 109 can be a neodymium magnet, where top plate 109 is a material that is a neodymium, iron, and boron alloy. However, examples of the disclosure are not so limited. For example, top plate 109 can be iron, nickel, a nickel-iron alloy such as Mu-metal, and/or any other magnetic materials, composites, rare-earth magnets, other magnetic alloys, and/or other combinations of materials.

Magnetic plate 102, pole plate 104, top plate 109, and side magnet 111 can generate a magnetic field in channel 108. As used herein, the term “magnetic field” can, for example, refer to a force field that is created by moving electric charges and magnetic dipoles. For example, magnetic dipoles of magnetic plate 102 and side magnet 111 can create a magnetic field in channel 108, as is further described in connection with FIG. 5.

Key 100 can include wire coil 106. As used herein, the term “wire coil” can, for example, refer to an electrical conductor in the shape of a coil, spiral, or helix. For example, wire coil 106 can be a wire in the shape of a coil. Wire coil 106 can be copper, aluminum, silver, beryllium, and/or any other metallic or non-metallic conductive material.

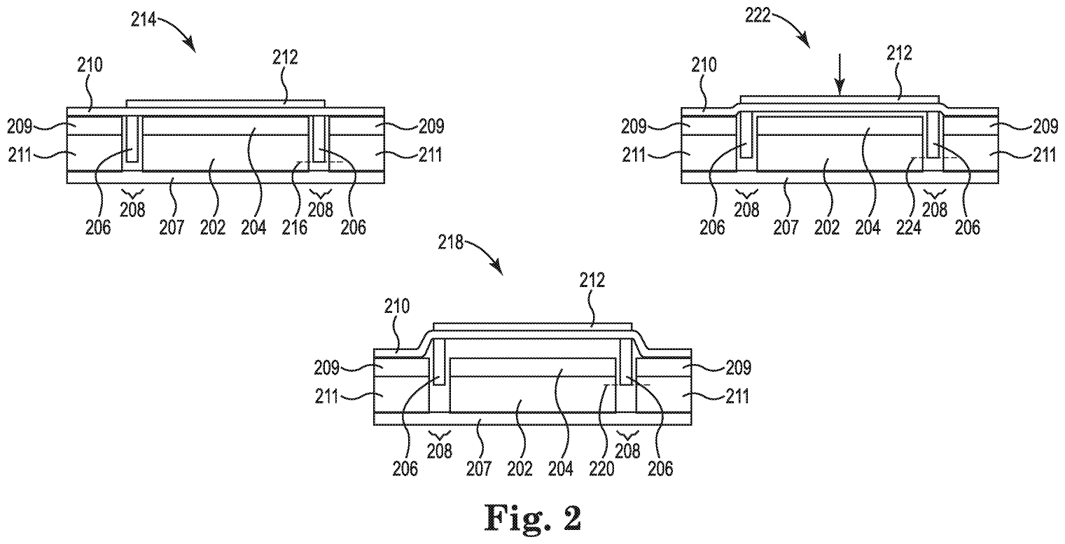

Wire coil 106 can be located in channel 108. For example, wire coil 106 can be located in channel 108 such that wire coil 106 can interact with the magnetic field generated by magnetic plate 102, pole plate 104, top plate 109, and side magnet 111, as is further described with respect to FIGS. 2-4.

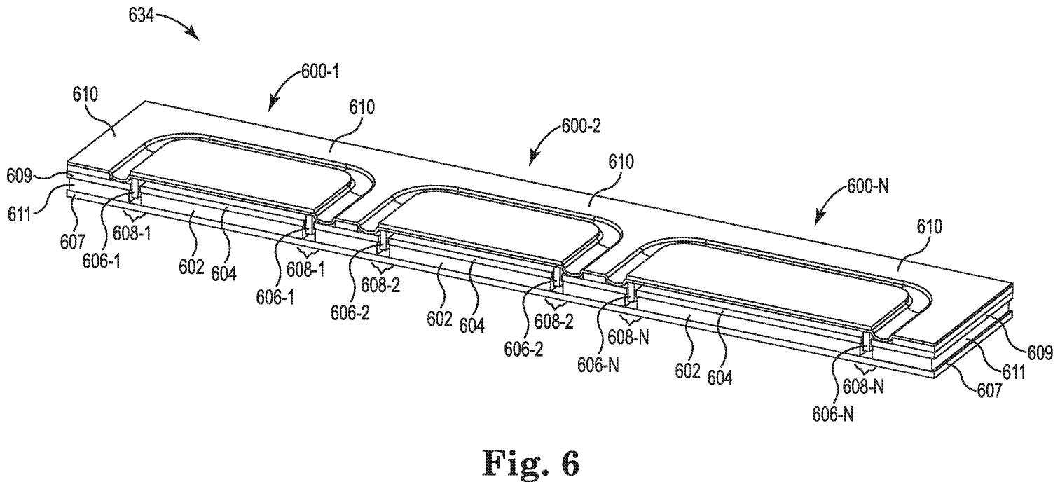

As illustrated in FIG. 1, membrane 110 can cover pole plate 104, channel 108, and top plate 109. As used herein, the term “membrane” can, for example, refer to a flexible structure acting as a boundary between two areas. For example, membrane 110 can cover pole plate 104, channel 108, and/or other components of key 100 to ensure debris and/or liquids are not able to pass through membrane 110 to interact with pole plate 104, magnetic plate 102, wire coil 106, and/or other components of key 100, as is further described in connection with FIG. 6. Membrane 110 can be a polypropylene membrane, a Mylar membrane, and/or any other flexible material to prevent debris and/or liquid from interacting with components of key 100.

Key 100 can include keycap 112. As used herein, the term “keycap” can, for example, refer to a cover of a key that is illustrated to indicate a function of the key and/or an alphanumeric character the key corresponds to. For example, keycap 112 can be illustrated with the letter “A”, indicating key 100 corresponds to the alphanumeric character “A”. In other words, when key 100 is pressed, a computing device can receive the alphanumeric character “A” as the input from key 100. As illustrated in FIG. 1, keycap 112 can be located on top of membrane 110. Keycap 112 can be stainless steel, titanium, plastic, fiber, carbon fiber, and/or any other suitable material.

The components of key 100 can be located on base plate 107. As used herein, the term “base plate” can, for example, refer to a piece of material which can include mechanical and electrical connections for key 100. For example, base plate 107 can function to be a plate on which components of key 100 (e.g., magnetic plate 102, pole plate 104, side magnet 111, top plate 109) can rest and/or be attached/connected to.

FIG. 2 illustrates a side view of an example of a key with a wire coil 206 at different positions 216, 220, 224 in a channel 208 consistent with the disclosure. As illustrated in FIG. 2, the key can be at a resting position 214, a first position 218, or a second position 222. Similar to key 100, previously described in connection with FIG. 1, the key can include components including a magnetic plate 202, a pole plate 204, a wire coil 206, a base plate 207, a channel 208, top plate 209, a membrane 210, side magnet 211, and a keycap 212. The key can include the above listed components at the three different positions (e.g., resting position 214, first position 218, and second position 222).

Magnetic plate 202 can be located adjacent to pole plate 204. Channel 208 through magnetic plate 202 and pole plate 204 can be located adjacent to a perimeter edge of magnetic plate 202 and a perimeter edge of pole plate 204, as well as a perimeter edge of top plate 209 and side magnet 211. Membrane 210 can cover pole plate 204, channel 208 and top plate 209.

Magnetic plate 202, pole plate 204, top plate 209, and side magnet 211 can generate a magnetic field in channel 208. For example, magnetic dipoles of magnetic plate 202 and side magnet 211 can generate a magnetic field in channel 208.

Wire coil 206 can be located in channel 208 and be connected to keycap 212. A connection between wire coil 206 and keycap 212 can allow for movement of wire coil 206 to occur in channel 208 when movement of keycap 212 occurs. For example, when keycap 212 is depressed, wire coil 206 can correspondingly move in channel 208, as is further described herein.

As illustrated in FIG. 2, the key can be at a resting position 214. In such an example, a resting position can refer to the key being fully depressed. The resting position 214 of the key can correspond to the keyboard being powered down. For instance, in an example in which the keyboard is included in a laptop computer, the key can be fully depressed in resting position 214 when the laptop computer is powered off, in sleep mode, having a display in a closed position, etc. The wire coil 206 can be correspondingly located at a resting position 216 in channel 208 when the key is in resting position 214.

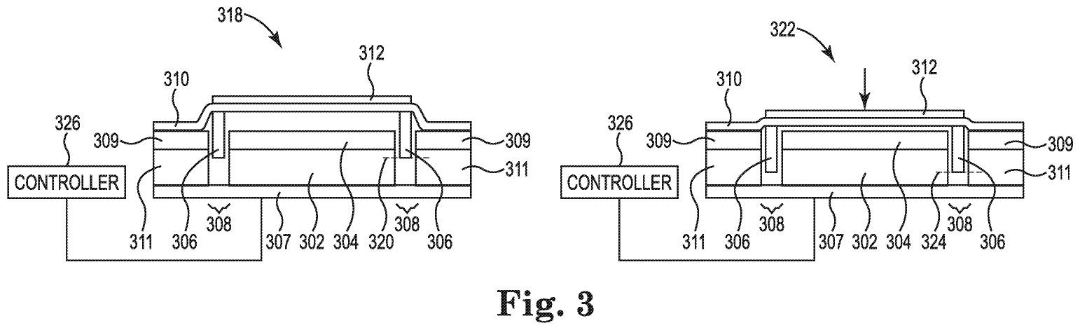

A controller (e.g., not illustrated in FIG. 2) can apply a DC voltage to wire coil 206. Application of the DC voltage to wire coil 206 can cause the wire coil 206 to interact with the magnetic field generated by magnetic plate 202, pole plate 204, top plate 209, and side magnet 211. For example, the magnetic field generated by magnetic plate 202, pole plate 204, top plate 209, and side magnet 211 can cause a magnetic force to be applied to wire coil 206 when the DC voltage is applied to wire coil 206. As used herein, the term “magnetic force” can, for example, refer to a force arising between electrically charged particles. Electrical connections from the controller to the wire coil 206 can be made through base plate 207, as is further described in connection with FIG. 3.

Wire coil 206 can be raised from a resting position 216, illustrated in FIG. 2 as key at resting position 214, to a first position 220, illustrated in FIG. 2 as key at first position 218. Wire coil 206 can be raised from resting position 216 to first position 220 in channel 208. For example, application of the DC voltage to wire coil 206 can cause wire coil 206 to be raised from resting position 216 to first position 220. For example, the magnetic field generated by magnetic plate 202, pole plate 204, top plate 209, and side magnet 211 and a positive DC voltage applied to wire coil 206 can cause interaction between electrically charged particles of wire coil 206 to cause the wire coil 206 to rise from resting position 216 to first position 218 in channel 208.

In some examples, wire coil 206 can be mechanically suspended at first position 220. For example, wire coil 206 can be mechanically suspended at first position 220 via a mechanical mechanism.

The controller can apply the DC voltage to wire coil 206 to move wire coil 206 from resting position 216 to first position 220 in response to the keyboard being powered on. For example, the key can be moved from resting position 214 to first position 218 by applying the DC voltage to wire coil 206 to move wire coil 206 from the resting position 216 to first position 220 when, for instance, a laptop computer including the keyboard is powered on, exits sleep mode, has the display opened, etc. Moving the key from resting position 214 to first position 218 can allow the keys of the keyboard to rise to first position 220 such that a user depressing a key can result in an input to the keyboard.

The controller can modify a location of first position 220 of wire coil 206. For example, the controller can modify the location of first position 220 to be higher or lower. The location of first position 220 can be a user preference. In some examples, a user may prefer first position 220 to be higher, resulting in a longer key travel. In some examples, a user may prefer first position 220 to be lower, resulting in a shorter key travel.

In some examples, the controller can modify the location of first position 220 to be higher by increasing the DC voltage applied to wire coil 206. For example, increasing the DC voltage applied to wire coil 206 can increase the height of the location of first position 220 in channel 208.

In some examples, the controller can modify the location of first position 220 to be lower by decreasing the DC voltage applied to wire coil 206. For example, decreasing the DC voltage applied to wire coil 206 can decrease the height of the location of first position 220 in channel 208.

As illustrated in FIG. 2, the key at first position 218 can be depressed such that the key is at second position 222. For example, a user of the keyboard may press the key from first position 218 to second position 222 in order to cause an input to the keyboard to occur.

As the key moves from first position 218 to second position 222, wire coil 206 can correspondingly move from first position 220 to second position 224. Wire coil 206 can generate an AC voltage in response to wire coil 206 moving from first position 220 to second position 224. For example, the magnetic field generated by magnetic plate 202, pole plate 204, top plate 209, and side magnet 211 and the DC voltage applied to wire coil 206 can cause an AC voltage to be generated as the wire coil 206 moves from first position 220 to second position 224. In other words, AC is generated in response to keycap 212 (e.g., and the key) being pressed down from first position 218 to second position 222.

The AC generated in response to wire coil 206 moving in channel 208 can correspond to a change in voltage of wire coil 206. For example, the AC generated by wire coil 206 in response to wire coil 206 moving from first position 220 to second position 224 in channel 208 can cause a change in voltage of wire coil 206. The controller can determine, based on the change in voltage of wire coil 206, that a key press has occurred, as is further described in connection with FIG. 3.

FIG. 3 illustrates a side view of an example of a key with a wire coil 306 being moved from a first position 320 to a second position 324 consistent with the disclosure. As illustrated in FIG. 3, the key can be at a first position 318 or a second position 322. Similar to key 100, previously described in connection with FIG. 1, the key can include components including a magnetic plate 302, a pole plate 304, a wire coil 306, a base plate 307, a channel 308, a top plate 309, a membrane 310, a side magnet 311, and a keycap 312. The key can include the above listed components at the two different positions (e.g., first position 318 and second position 322).

Magnetic plate 302 can be located adjacent to pole plate 304. Channel 308 through magnetic plate 302 and pole plate 304 can be located adjacent to a perimeter edge of magnetic plate 302 and a perimeter edge of pole plate 304, as well as a perimeter edge of top plate 309 and side magnet 311. Membrane 310 can be continuous and cover pole plate 304 and channel 308.

Magnetic plate 302, pole plate 304, top plate 309, and side magnet 311 can generate a magnetic field in channel 308. For example, magnetic dipoles of magnetic plate 302 and side magnet 311 can generate a magnetic field in channel 308.

Wire coil 306 can be located in channel 308 and be connected to keycap 312. A connection between wire coil 306 and keycap 312 can allow for movement of wire coil 306 to occur in channel 308 when movement of keycap 312 occurs. For example, when keycap 312 is depressed, wire coil 306 can correspondingly move in channel 308, as is further described herein.

The key can be connected to controller 326. For example, controller 326 can be connected to the key via base plate 307. For example, base plate 307 can include electrical connections such that signals from keys of the keyboard can be transmitted to and/or from controller 326. Although not illustrated in FIG. 3 for clarity and so as not to obscure examples of the disclosure, controller 326 can include a processing resource and a memory resource. The memory resource can store instructions that are executed by the processing resource to perform functions described herein.

Controller 326 can apply a DC voltage to wire coil 306 via base plate 307 to move wire coil 306 to first position 320 in channel 308. For example, controller 326 can apply the DC voltage to wire coil 306 so that the key is in first position 318. The key can be depressed by a user from first position 318 to second position 322 in order to cause an input to the keyboard to occur.

Controller 326 can detect an AC voltage via base plate 307 in response to wire coil 306 moving from first position 320 in channel 308 to second position 324 in channel 308. For example, as illustrated at second position 322 of the key in FIG. 3, a user has pressed down on keycap 312 causing wire coil 306 to move from first position 320 to second position 324. An AC voltage can be generated by wire coil 306 as a result of wire coil 306 moving through the magnetic field in channel 308 and the DC voltage applied to wire coil 306. Controller 326 can detect the AC voltage generated by wire coil 306 via electrical connections in base plate 307 connecting the key and controller 326.

Controller 326 can determine, based on the AC voltage generated by wire coil 306 moving to second position 324 in channel 308 exceeding a threshold AC voltage, a key press of the key having occurred. For example, controller 326 can determine the wire coil 306 moving from first position 320 to second position 324 generated 3 volts (V). Based on the threshold AC voltage being 2 V, controller 326 can determine a key press has occurred.

Although controller 326 is described above as determining a key press of the key having occurred based on the AC voltage generated by wire coil 306 exceeding a threshold AC voltage, examples of the disclosure are not so limited. For example, controller 326 can determine a key press of the key having occurred based on the AC voltage generated by wire coil 306 being the same as the threshold AC voltage. For instance, controller 326 can determine the wire coil 306 moving from first position 320 to second position 324 generated 3 volts (V). Based on the threshold AC voltage being 3 V, controller 326 can determine a key press has occurred.

In some examples, controller 326 can generate a haptic feedback in response to the key press being determined. As used herein, the term “haptic feedback” can, for example, refer to a stimulation to indicate an action has been completed. For example, haptic feedback can include a vibration to indicate a key press has occurred.

Controller 326 can generate a haptic feedback in response to the key press having occurred by applying a pulse of DC voltage to wire coil 306 via base plate 307. For example, in response to controller 326 determining the key press has occurred (e.g., in response to controller 326 determining that the AC voltage generated by wire coil 306 in response to wire coil moving from first position 320 to second position 324 in channel 308 is the same as or exceeds a threshold AC voltage), controller 326 can apply a pulse of DC voltage to wire coil 306 via base plate 307. The pulse of DC voltage to wire coil 306 can cause a vibration in the key. The vibration in the key can indicate to a user that a key press has occurred.

Controller 326 can modify a location of second position 324 of wire coil 306. For example, the controller 326 can modify the location of second position 324 to be higher or lower. The location of second position 324 can be a user preference. In some examples, a user may prefer second position 324 to be higher, resulting in a shorter key travel. In some examples, a user may prefer second position 324 to be lower, resulting in a longer key travel.

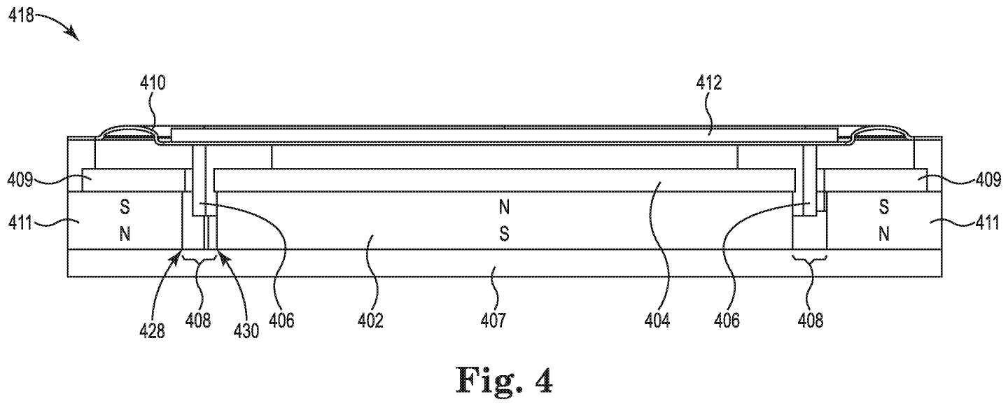

FIG. 4 illustrates a side view of an example of a key 400 with a magnetic plate 402 and a pole plate 404 having opposite poles consistent with the disclosure. As illustrated in FIG. 4, similar to key 100, previously described in connection with FIG. 1, key 400 can include components including a magnetic plate 402, a pole plate 404, a wire coil 406, base plate 407, a channel 408, a top plate 409, a membrane 410, a side magnet 411, and a keycap 412. Channel 408 can include a first side 428 and a second side 430.

As previously described, magnetic plate 402, pole plate 404, top plate 409, and side magnet 411 can generate a magnetic field in channel 408 as a result of opposing poles between the magnetic plate 402 and side magnets 411. The magnetic field can be generated as a result of magnetic dipoles of magnetic plate 402 and side magnet 411.

As illustrated in FIG. 4, magnetic plate 402 and side magnet 411 can include poles on a first side 428 of channel 408 that are opposite to poles on a second side 430 of channel 408. For example, in the orientation illustrated in FIG. 4, side magnet 411 on the left side of FIG. 4 can include S-N poles, whereas magnetic plate 402 on second side 430 of channel 408 can include N-S poles. Similarly, side magnet 411 on the right side of FIG. 4 can include S-N poles, whereas magnetic plate 402 can include N-S poles. In other words, magnetic plate 402 and side magnets 411 can include poles that are opposite on opposing sides of channel 408 as oriented in FIG. 4.

FIG. 5 illustrates a perspective view 532 of an example of a key 500 consistent with the disclosure. As illustrated in FIG. 5, key 500 can include pole plate 504, wire coil 506, and channel 508.

Similar to key 100, previously described in connection with FIG. 1, key 500 can include components including a magnetic plate (e.g., not illustrated in FIG. 5), a pole plate 504, a wire coil 506, a channel 508, a membrane (e.g., not illustrated in FIG. 5), and a keycap (e.g., not illustrated in FIG. 5).

As illustrated in FIG. 5, channel 508 can be adjacent to a perimeter edge of the magnetic plate and pole plate 504. In the orientation illustrated in FIG. 5, the magnetic plate is not visible, as pole plate 504 is located on top of the magnetic plate.

For example, channel 508 can be adjacent to the perimeter edge of the magnetic plate and pole plate 504. Channel 508 can be a groove creating a space between two sides of the magnetic plate and pole plate 504. Channel 508 can follow the shape of the magnetic plate and pole plate 504. For example, as illustrated in FIG. 5, the magnetic plate and pole plate 504 are a rectangular shape with radiused corners. Correspondingly, channel 508 can be a channel that is adjacent to the perimeter edges of the magnetic plate and pole plate 504, creating a rectangularly shaped channel 508 with corresponding radiused corners.

Wire coil 506 can be located in channel 508. Wire coil 506 can be in an orientation such that wire coil 506 follows the path of channel 508.

FIG. 6 illustrates a perspective view of a cut-away of an example of a portion 634 of a keyboard with keyboard keys 600 consistent with the disclosure. As illustrated in FIG. 6, portion 634 of the keyboard can include keys 600, top plate 609, side magnets 611, membrane 610, and base plate 607.

Key 600-1 can include a magnetic plate 602, a pole plate 604, a wire coil 606-1, and a channel 608-1. Similarly, key 600-2 can include a magnetic plate 602, a pole plate 604, a wire coil 606-2, and a channel 608-2, and key 600-N can include a magnetic plate 602, a pole plate 604, a wire coil 606-N, and a channel 608-N.

As previously described, an AC voltage can be generated based on a wire coil 606 moving in a channel 608 of a particular key when the particular key is pressed by a user. For example, a user may press key 600-1, causing wire coil 606-1 to move in channel 608-1, resulting in an AC voltage being generated by wire coil 606-1. A controller can detect the AC voltage generated by wire coil 606-1, and determine based on the detected AC voltage that key 600-1 has been pressed.

Top plate 609 can be continuous. For example, top plate 609 can be a continuous plate through which portions of top plate 609 are cut out that correspond to locations of individual keys 600-1, 600-2, 600-3. For example, portions of top plate 609 may be removed so that keys 600-1, 600-2, 600-3 and their respective components may be located. Keys 600-1, 600-2, 600-3 may share side top plate 609 with an adjacent key.

Similar to top plate 609, side magnet 611 can be continuous. For example, side magnet 611 can be a continuous magnet through which portions of side magnet 611 are cut out that correspond to locations of individual keys 600-1, 600-2, 600-3. For example, portions of side magnet 611 may be removed so that keys 600-1, 600-2, 600-3 and their respective components may be located. Keys 600-1, 600-2, 600-3 may share side magnet 611 with an adjacent key.

The keyboard can include membrane 610. Membrane 610 can be a continuous membrane covering keys 600. For example, membrane 610 can be continuous such that membrane 610 covers keys 600-1, 600-2, 600-N. Membrane 610 can shield debris, such as liquid from contacting keys 600. For example, membrane 610 can shield liquid from contacting magnetic plates 602, pole plates 604, wire coils 606, and/or other components of keys 600. In some examples, membrane 610 can be vacuum formed as a continuous sheet of material over the keys 600 of the keyboard to provide a continuous liquid and/or other debris proof surface.

Keyboard keys, according to the disclosure, can allow for a debris proof keyboard. For example, keyboard keys according to the disclosure can allow for a liquid proof keyboard such that liquid contacting the membrane 610 can be prevented from contacting components of the keys. The magnetic plate, pole plate, and wire coil allow for detection of key presses while providing for a thin keyboard thickness profile. The thin keyboard thickness profile can allow for keyboards and/or various computing devices to have a thin profile.

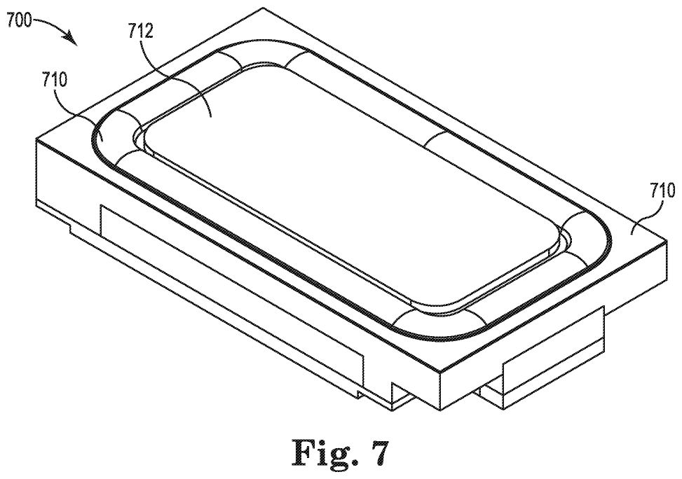

FIG. 7 illustrates a perspective view of an example of a key 700 consistent with the disclosure. As illustrated in FIG. 7, key 700 can include membrane 710 and keycap 712.

As illustrated in FIG. 7, keycap 712 can be located on top of membrane 710. A user can press keycap 712 to input a character and/or other symbols into a computing device connected with a keyboard including key 700 via a keypress.

Membrane 710 can be continuous in order to cover components of key 700. Although not illustrated in FIG. 7 for clarity and so as not to obscure examples of the disclosure, the keyboard can include other keys adjacent to key 700. Membrane 710 can be continuous to cover components of keys adjacent to key 700, as well as other keys of the keyboard.

In the foregoing detailed description of the disclosure, reference is made to the accompanying drawings that form a part hereof, and in which is shown by way of illustration how examples of the disclosure may be practiced. These examples are described in sufficient detail to enable those of ordinary skill in the art to practice the examples of this disclosure, and it is to be understood that other examples may be utilized and that process, electrical, and/or structural changes may be made without departing from the scope of the disclosure.

The figures herein follow a numbering convention in which the first digit corresponds to the drawing figure number and the remaining digits identify an element or component in the drawing. Similar elements or components between different figures may be identified by the use of similar digits. For example, 102 may reference element “02” in FIG. 1, and a similar element may be referenced as 202 in FIG. 2.

Elements illustrated in the various figures herein can be added, exchanged, and/or eliminated so as to provide a plurality of additional examples of the disclosure. In addition, the proportion and the relative scale of the elements provided in the figures are intended to illustrate the examples of the disclosure, and should not be taken in a limiting sense. As used herein, the designator “N”, particularly with respect to reference numerals in the drawings, indicate that a plurality of the particular feature so designated can be included with examples of the disclosure. The designator can represent the same or different numbers of the particular features. As used herein, “a plurality of” an element and/or feature can refer to more than one of such elements and/or features.

What is claimed:

1. A key of a keyboard, comprising:
a magnetic plate;
a pole plate located adjacent to the magnetic plate, wherein a channel through the magnetic plate and the pole plate is located adjacent to a perimeter edge of the magnetic plate and a perimeter edge of the pole plate;
a membrane covering the pole plate and the channel;
a keycap located on top of the membrane; and
a wire coil connected to the keycap and located in the channel.

2. The key of claim 1, wherein the magnetic plate and the pole plate are to generate a magnetic field in the channel.

3. The key of claim 1, wherein the wire coil is to raise from a resting position to a first position in response to a direct current (DC) voltage being applied to the wire coil.

4. The key of claim 1, wherein the wire coil is to be mechanically suspended at a first position.

5. The key of claim 1, wherein an alternating current (AC) is to be generated in response to the wire coil moving in the channel.

6. The key of claim 5, wherein the AC generated corresponds to a change in voltage of the wire coil as a result of the keycap being pressed down.

7. A key of a keyboard, comprising:
a pole plate;
a magnetic plate located adjacent to the pole plate, wherein:
a channel through the magnetic plate and the pole plate is located adjacent to a perimeter edge of the magnetic plate and a perimeter edge of the pole plate; and
the magnetic plate and the pole plate are to generate a magnetic field in the channel;
a membrane covering the pole plate and the channel; and
a wire coil connected to a keycap and located in the channel, wherein a direct current (DC) voltage is to be applied to the wire coil;
wherein the wire coil is to generate an alternating current (AC) voltage in response to the wire coil moving from a first position in the channel to a second position in the channel.

8. The key of claim 7, wherein a key press of the key is to be determined in response to the generated AC voltage exceeding a threshold AC voltage.

9. The key of claim 8, wherein a haptic feedback is to be generated in response to the key press being determined by applying a pulse of DC voltage to the wire coil.

10. The key of claim 7, wherein the magnetic plate and the pole plate are to generate the magnetic field in the channel via opposing poles.

11. A keyboard, comprising:
a key, comprising:
a pole plate;
a magnetic plate located adjacent to the pole plate, wherein the magnetic plate and the pole plate are to generate a magnetic field in a channel located adjacent to a perimeter edge of the magnetic plate and a perimeter edge of the pole plate;
a continuous membrane covering the pole plate and the channel; and
a wire coil located in the channel;
a controller to:
apply a direct current (DC) voltage to the wire coil to move the wire coil to a first position in the channel;
detect an alternative current (AC) voltage in response to the wire coil moving from the first position to a second position in the channel, wherein the wire coil moves from the first position to the second position based on a keycap connected to the wire coil being depressed; and
determine, based on the AC voltage generated by the wire coil moving to the second position exceeding a threshold AC voltage, a key press of the key having occurred.

12. The keyboard of claim 11, wherein the controller is to generate a haptic feedback in response to the key press having occurred by applying a DC voltage pulse to the wire coil.

13. The keyboard of claim 11, wherein the controller is to modify a location of the first position by modifying the DC voltage applied to the wire coil.

14. The keyboard of claim 11, wherein the controller is to apply the DC voltage to the wire coil to move the wire coil from a resting position to the first position in response to the keyboard powering on.

15. The keyboard of claim 11, wherein:
the keyboard includes a plurality of keys; and
the continuous membrane is to cover the plurality of keys to shield the plurality of keys from liquid.
